(19) United States
(12) Patent Application Publication
(10) Pub. No.: US 2026/0148765 A1
(43) Pub. Date: May 28, 2026

(54) MEMORY CIRCUITS AND METHODS FOR LATCHING READOUT IN MULTI-BANK SRAM MEMORY

(71) Applicant: Taiwan Semiconductor Manufacturing Company, Ltd., Hsinchu (TW)

(72) Inventors: Abhishek Pathak, Hsinchu City (TW); Atul Katoch, Hsinchu City (TW)

(73) Assignee: Taiwan Semiconductor Manufacturing Company, Ltd., Hsinchu (TW)

(21) Appl. No.: 18/960,648

(22) Filed: Nov. 26, 2024

(51) Int. Cl. G11C 11/419; G11C 11/412; G11C 11/418

(52) U.S. Cl. CPC G11C 11/419; G11C 11/412; G11C 11/418

(57) ABSTRACT

A memory circuit may comprise at least one of: a first memory bank, a first local input/output (I/O) circuit, a second memory bank, a second local I/O circuit, a global I/O circuit, a first local latch circuit, and a second local latch circuit. The first memory bank may include a first memory array. The second memory bank may include a second memory array. The first local latch circuit can be configured to be activated to latch data bit when read from the first memory array. The second local latch circuit can be configured to be activated to latch data bit when read from the second memory array. The first local latch circuit and the second local latch circuit can be configured to be alternately activated.

### BACKGROUND

The semiconductor industry has experienced rapid growth due to continuous improvements in the integration density of a variety of electronic components (e.g., transistors, diodes, resistors, capacitors, etc.). For the most part, this improvement in integration density has come from repeated reductions in minimum feature size, which allows more components to be integrated into a given area.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 illustrates an example block diagram of a memory circuit, in accordance with some embodiments.

FIG. 2 illustrates an example schematic diagram of a portion of the memory circuit of FIG. 1, in accordance with some embodiments.

FIG. 3 illustrates example waveforms of various signals while operating the memory circuit of FIG. 2, in accordance with some embodiments.

FIG. 4 illustrates another example block diagram of a memory circuit, in accordance with some embodiments.

FIG. 5 illustrates an example circuit diagram of a sense amplifier, in accordance with some embodiments.

FIG. 6 illustrates another example block diagram of a memory circuit, in accordance with some embodiments.

FIG. 7 illustrates another example block diagram of a memory circuit, in accordance with some embodiments.

FIG. 8 illustrates an example flow chart for operating a memory circuit, in accordance with some embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over, or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” “top,” “bottom” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

A static random access memory (SRAM) device is a type of volatile semiconductor memory that stores data bits using bi-stable circuitry. Bi-stable circuitry will maintain the integrity of a stored bit without refreshing. A single SRAM cell is generally referred to as a bit cell because the single SRAM cell stores one bit of information, represented by a logic state of two cross coupled inverters. A memory array includes multiple bit cells arranged in rows and columns. In some approaches, each bit cell in a memory array includes a connection to a power supply voltage and a connection to a reference voltage. Logic signals on first access lines (e.g., bit lines) control reading from and writing to a bit cell, with a second access line (e.g., a word line) controlling connections of the bit lines to the cross-coupled inverters through pass gates. When the pass gates are in a non-conductive state, the bit cell floats.

In a multi-bank SRAM memory, the process of reading from memory is governed by a complex self-timed operation, which inherently introduces multiple signal races. For example, a LAT signal may need to rise before the SAE signal, as any delay can cause a reduction in the effective latch write window. The LAT signal should fall before SAE falls; otherwise, a floating RGBLB signal becomes susceptible to noise. These races emphasize the importance of precise signal timing to maintain memory reliability and performance. These races create challenges in ensuring proper functionality, as they involve intricate logic circuits that are sensitive to device and metal variations. Such variations can significantly impact the yield of the memory. To mitigate these issues, rigorous design validation must be performed across multiple process, voltage, and temperature corners, ensuring that the logic behaves correctly in silicon. However, to accommodate these variations, designers often incorporate extra timing margins into the design. While these margins ensure reliability, the margins also limit the overall performance of the memory, resulting in a trade-off between yield and speed.

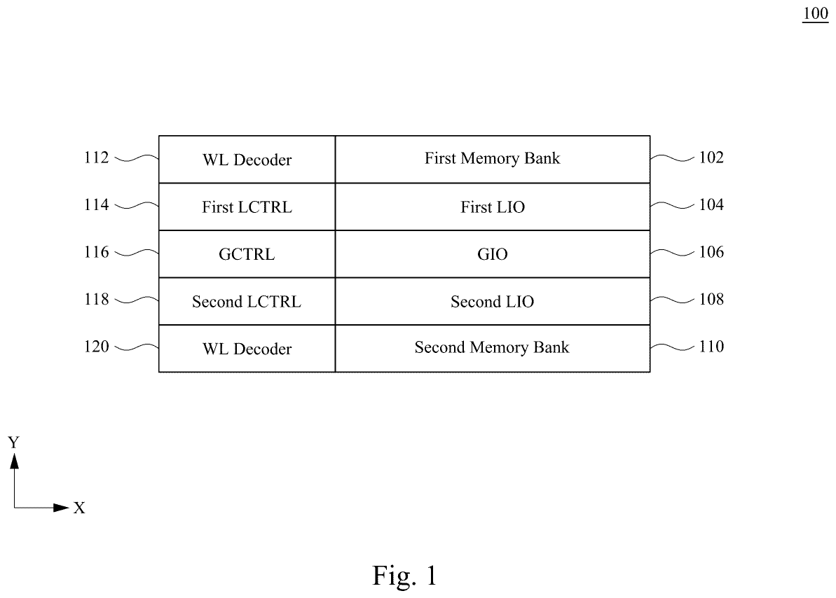

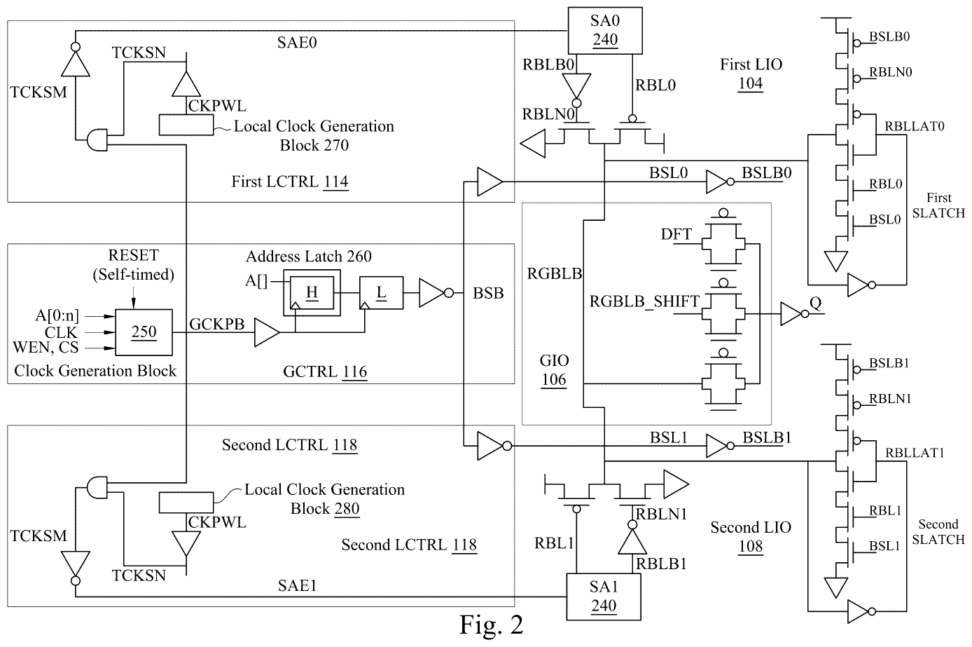

In a memory system, data from a bit cell is read through local bit-lines using differential sensing in an input/output (I/O) circuit of a local bank (e.g., sense amplifier (SA) in first LIO/second LIO blocks as depicted in FIGS. 1 and 2). Once a sufficient differential signal is developed on the local bit-lines, a self-timed signal (e.g., RESET) can be generated by tracking logic, which then may trigger the sense amplifier enable signals (e.g., SA0/SA1). The read data from the sense amplifiers (e.g., SA0/SA1) can be transferred to a global bit-line (e.g., RGBLB), which is shared between the memory banks. In certain embodiments, the data can be latched into the Global I/O (GIO) using a clocked signal. The LAT signal can be a replica of the sense amplifier enable signal (SAE) generated by a global control block (GCTRL). In certain embodiments, it is carefully positioned to ensure that the latch in GIO opens before data begins transferring from the local I/O to the RGBLB and closes before the RGBLB stops driving the data, preventing the bit-line from floating. However, the positioning of the LAT signal introduces multiple races between the clocked signals, which require careful timing management.

In some memory architectures, latching read data in a global I/O (GIO) requires the generation of replica logic for sense amplifier enable signals, which introduce multiple races between signals. In the present application, the read data is latched directly in a local latch circuit (e.g., first S-LATCH, second S-LATCH) within the local I/O (e.g., first LIO, second LIO), using the respective SAE0/SAE1 signals from SA0/SA1. This approach eliminates all races associated with the global latching circuit. The design of the local latch circuit allows the readout data itself to open and close the latch. A bank select signal (e.g., BSL0, BSL1), generated based on the address (A[ ]), may select the corresponding local latch circuit (e.g., first S-LATCH, second S-LATCH) at the start of the read operation and remain unchanged until the next active clock cycle. In certain embodiments, both latches may hold the same data, ensuring no glitches occur on the signals (e.g., RGBLB) when switching between banks. The proposed circuit provides several advantages: eliminating internal clock races improves yield, reducing the resources and time needed for timing convergence, and boosting performance by removing the need for additional margin in tracking circuits. The self-latch concept, where the SA clock serves as the latch clock, also negates the need for extra tracking circuits. Furthermore, the additional latches can be incorporated without any area penalty.

The present disclosure provides various embodiments of a memory circuit comprising a first memory bank, a first local input/output (I/O) circuit, a second memory bank, a second local I/O circuit, a global I/O circuit, a first local latch circuit, and a second local latch circuit. The first memory bank may include a first memory array. The first local I/O circuit can be operatively coupled to the first memory bank. The second memory bank may include a second memory array. The second local I/O circuit can be operatively coupled to the second memory bank. The global I/O circuit can be operatively coupled between the first local I/O circuit and the second local I/O circuit. The global I/O circuit can be configured to latch a data bit read from the first memory array through the first local I/O circuit or read from the second memory array through the second local I/O circuit. The first local latch circuit can be operatively coupled to the first local I/O circuit. The first local latch circuit can be configured to be activated to latch the data bit when read from the first memory array. The second local latch circuit can be operatively coupled to the second local I/O circuit. The second local latch circuit can be configured to be activated to latch the data bit when read from the second memory array. In some embodiments, the first local latch circuit and the second local latch circuit can be configured to be alternately activated. The proposed memory circuit eliminates all signal races involved in reading from multibank SRAM memory, thereby improving both the yield and performance of the memory.

FIG. 1 illustrates an example block diagram of a memory circuit 100, in accordance with various embodiments of the present disclosure. In general, the memory circuit 100 may include a plural number of SRAM cells. However, the memory cells of the memory circuit 100 can be adapted for other semiconductor memories including, but not limited to, dynamic random access memories (“DRAMs”), erasable programmable read only memories (“EPROMs”), and electronically erasable programmable read only memories (“EEPROMs”) as well as other read only memories (“ROMs”), random access memories (“RAMs”), and flash memories. It should be understood that the block diagram of FIG. 1 has been simplified for illustrative purposes, and thus, the memory circuit 100 can include any of various other components or circuits, while remaining within the scope of the present disclosure. For example, the memory circuit 100 can include one or more tracking circuits.

In some embodiments, the memory circuit 100 may include at least one of: a first memory bank 102, a first local input/output (I/O) circuit (LIO) block 104, a second memory bank 110, a second local I/O circuit (LIO) block 108, or a global I/O circuit (GIO) block 106. In some embodiments, the first LIO block 104 may include a first local latch circuit. In some embodiments, the second LIO 108 block may include a second local latch circuit. In some embodiments, the memory circuit 100 may further include a number of word line (WL) decoder blocks 112, 120, a number of local control (LCTRL) blocks 114, 118, and a global control (GCTRL) block 116.

In some embodiments, the first memory bank 102 may include a plurality of first memory arrays, which can include a number of SRAM cells. The first memory bank 102 can be operatively coupled with a corresponding one of the LIO blocks (e.g., first LIO 104), a corresponding one of the LCTRL blocks (e.g., first LCTRL 114), and a corresponding one of the WL decoder blocks (e.g., WL decoder 112). The SRAM cells may each be implemented as a six-transistor (6T) SRAM cell. However, the SRAM cells may be implemented as any of various other configurations such as, for example, an eight-transistor (8T) SRAM cell, a ten-transistor (10T) SRAM cell, etc., while remaining within the scope of the present disclosure. A 6T SRAM cell typically includes a first pass-gate transistor configured to selectively connect a pair of cross-coupled inverters to a first bit line, and a second pass-gate transistor configured to selectively connect the cross-coupled inverters to a second bit line. The first pass-gate transistor and the second pass-gate transistor are both configured to be activated for enabling the access (e.g., read, write) of the SRAM cell based on a signal supplied by the WL decoder 112.

In some embodiments, the first local I/O circuit block 104 can be operatively coupled to the first memory bank 102. The first LIO block 104 can be operatively coupled to the GIO block 106. The different LCTRL blocks 114, 118 and the different WL decoder blocks 112, 120 can be operatively coupled to the GCTRL block 116. In some embodiments, the first local I/O circuit block 104 can be physically disposed between the first memory bank 102 and the global I/O circuit block 106 along a lateral direction (e.g., Y direction).

In some embodiments, the second memory bank 110 may include a plurality of second memory arrays, which can include a number of SRAM cells. The second memory bank 110 can be operatively coupled with a corresponding one of the LIO blocks (e.g., second LIO 108), a corresponding one of the LCTRL blocks (e.g., second LCTRL 118), and a corresponding one of the WL decoder blocks (e.g., WL decoder 120). The SRAM cells may each be implemented as a six-transistor (6T) SRAM cell. However, the SRAM cells may be implemented as any of various other configurations such as, for example, an eight-transistor (8T) SRAM cell, a ten-transistor (10T) SRAM cell, etc., while remaining within the scope of the present disclosure. A 6T SRAM cell typically includes a first pass-gate transistor configured to selectively connect a pair of cross-coupled inverters to a first bit line, and a second pass-gate transistor configured to selectively connect the cross-coupled inverters to a second bit line. The first pass-gate transistor and the second pass-gate transistor are both configured to be activated for enabling the access (e.g., read, write) of the SRAM cell based on a signal supplied by the WL decoder 120.

In some embodiments, the second local I/O circuit block 108 can be operatively coupled to the second memory bank 110. The second LIO block 108 can be operatively coupled to the GIO block 106. The different LCTRL blocks 114, 118 and the different WL decoder blocks 112, 120 can be operatively coupled to the GCTRL block 116. In some embodiments, the second local I/O circuit block 108 can be physically disposed between the second memory bank 110 and the global I/O circuit block 106 along a lateral direction (e.g., Y-direction).

In some embodiments, the global I/O circuit block 106 can be operatively coupled between the first local I/O circuit block 104 and the second local I/O circuit block 108. In some embodiments, the global I/O circuit block 106 can be configured to latch a data bit read from the first memory back 102 (e.g., first memory array) through the first local I/O circuit block 104. In some embodiments, the global I/O circuit block 106 can be configured to latch a data bit read from the second memory bank 110 (e.g., second memory array) through the second local I/O circuit block 108. In some embodiments, the global I/O circuit block 106 can be physically disposed between the first memory bank 102 and the second memory bank 110 along a lateral direction (e.g., Y-direction), with the first local I/O circuit block 104 interposed between adjacent ones of the first memory arrays along the lateral direction (e.g., Y-direction) and with the second local I/O circuit block 108 interposed between adjacent ones of the second memory arrays along the lateral direction (e.g., Y-direction).

In some embodiments, a first local latch circuit can be operatively coupled to the first local I/O circuit block 104. The first local latch circuit can be configured to be activated to latch the data bit when read from the first memory bank 102 (e.g., first memory array). In some embodiments, the first local latch circuit can be physically disposed in the first local I/O circuit block 104. In certain embodiments, the first local latch circuit can be physically disposed next to the first local I/O circuit block 104.

In some embodiments, a second local latch circuit can be operatively coupled to the second local I/O circuit block 108. The second local latch circuit can be configured to be activated to latch the data bit when read from the second memory bank 110 (e.g., second memory array). In some embodiments, the second local latch circuit can be physically disposed in the second local I/O circuit block 108. In certain embodiments, the second local latch circuit can be physically disposed next to the second local I/O circuit block 108. In some embodiments, the first local latch circuit and the second local latch circuit can be configured to be alternately activated. For example, when the first local latch circuit is turned on, the second local latch circuit is turned off. Conversely, when the second local latch circuit is turned on, the first local latch circuit is turned off.

For example, the GCTRL block 116 can include a clock generator (or two clock generators, one configured for a read operation and the other configured for a write operation) to generate an internal clock signal (e.g., GCKPB signal). The GCKPB signal can control the reading and writing to and from the SRAM cells of the memory banks 102. In some embodiments, the clock generator can control a selection of a local latch circuit (e.g., first local latch circuit, or second local latch circuit). The GCTRL block 116 can include at least one X address decoder and one Y address decoder, which are configured to decode a first portion and a second portion of an address, respectively. The first portion of the address, upon being decoded, can be sent to the LIO block (e.g., 104) through the LCTRL block (e.g., 114) to identify one or more bit lines (BLs) of the memory bank 102; and the second portion of the address, upon being decoded, can be sent to the WL decoder block (e.g., 112) to assert one or more word lines (WLs) of the memory bank 102. In some embodiments, in a read active cycle, the internal clock signal (e.g., GCKPB) may set a BSL0/BSLB1 signal in a selected LIO (e.g., first LIO or second LIO) based on an address selection (e.g., A[ ]).

In various embodiments of the present disclosure, the LCTRL block (e.g., 114) can include a global read enable control circuit configured to generate a global read enable (READ) signal based on the GCKPB signal (provided by the GCTRL block 110). The LIO block (e.g., 104) can include a number of local read enable control circuits, each of which is operatively coupled to a respective set of SRAM cells of the corresponding memory bank 102. Each of the local read enable control circuits can be further controlled by a sense enable (SAE) signal generated by the LCTRL block 114. The SAE signal can be configured to activate/deactivate at least one sense amplifier circuit coupled to the corresponding set of SRAM cells. Details of these signals will be further discussed below.

In various embodiments, each memory bank (e.g., 102, 110) may have its corresponding LIO block (e.g., 104, 108) disposed next to itself along the Y-direction and its corresponding LCTRL block (e.g., 114, 118) disposed next to the LIO block (e.g., 104, 108) along the X-direction, as shown in the example of FIG. 1. Further, the GIO block 106 may be spaced from the memory bank 102, 110 with at least one LIO block 104, 108 interposed therebetween along the Y-direction; and the GCTRL block 116 may be disposed next to the GIO block 106 along the X-direction. However, it should be understood that the arrangement of the blocks of the memory circuit 100 can be configured differently, while remaining within the scope of the present disclosure.

FIG. 2 illustrates an example schematic diagram of a portion of the memory circuit 100, in accordance with various embodiments of the present disclosure. For example, the schematic diagram of FIG. 2 includes the first local IO circuit (first LIO) 104, the second local IO circuit (second LIO) 108, the global I/O circuit (GIO) 106, the first local control circuit (first LCTRL) 114, the global control circuit (GCTRL) 116, and the second local control circuit (second LCTRL) 118. In some embodiments, the first LIO 104 may include a first local latch circuit (e.g., first SLATCH). In some embodiments, the second LIO 108 may include a second local latch circuit (e.g., second SLATCH).

In some embodiments, the first LIO 104 can be coupled to a first memory array through a pair of first bit lines (e.g., RBLB0, RBL0). The first LIO 104 may include a first sense amplifier 210 (e.g., SAO) selectively activated by a first enable signal (e.g., SAE0). In some embodiments, when the first sense amplifier 210 is activated, one of the pair of first bit lines (e.g., RBLB0 or RBL0) rises and the other of the pair of first bit lines (e.g., RBL0 or RBLB0) falls, causing the data bit to be locally latched by a first local latch circuit 220 (e.g., first SLATCH). In some embodiments, the first local latch circuit 220 can be activated prior to the first sense amplifier 210 being activated. In some embodiments, the first local latch circuit 220 can be activated in response to the first memory bank being selected. In some embodiments, the sense amplifier signal (e.g., SAE0) can act as both a clock and a trigger for activating/opening the first local latch circuit 220. For example, at the beginning of an operation cycle, both RBLB0 signal and RBL0 signal in first LIO 104 remain high. The RBL0 signal may be 1, while the RBLN0 signal can be 0. When the first local latch 220 is selected, the BSLB0 signal can be 0. Since the first local latch 220 is selected, the data can be held in the first local latch 220. When the SAE0 signal goes high based on the data read from the memory array, either the RBLB0 signal can fall, or the RBL0 signal can fall. If the RBL0 signal falls, it may drive the PMOS in the first LIO 104, causing the RGBLB signal to go high. The RBL0 signal can also turn off the NMOS in the first local latch 220. In another example, if the RBLB0 signal falls, the RBLN0 signal can go high, driving the RGBLB signal low. The RBLN0 signal can turn off the PMOS in the first local latch 220, preventing any contention.

In some embodiments, the second LIO 108 can be coupled to a second memory array through a pair of second bit lines (e.g., RBLB1, RBL1). The second LIO 108 may include a second sense amplifier 240 (e.g., SA1) selectively activated by a second enable signal (e.g., SAE1). In some embodiments, when the second sense amplifier 240 is activated, one of the pair of second bit lines (e.g., RBLB1 or RBL1) rises and the other of the pair of second bit lines (e.g., RBL1 or RBLB1) falls, causing the data bit to be locally latched by a second local latch circuit 230 (e.g., second SLATCH). In some embodiments, the second local latch circuit 230 can be activated prior to the second sense amplifier 240 being activated. In some embodiments, the second local latch circuit 230 can be activated in response to the second memory bank being selected. In some embodiments, the sense amplifier signal (e.g., SAE1) can act as both a clock and a trigger for activating/opening the second local latch circuit 230.

In some embodiments, the GIO 106 can be operatively coupled between the first LIO 104 and the second LIO 108. The GIO 106 can be configured to latch a data bit (e.g., RGBLB) read from a first memory bank through the first LIO 104 or read from a second memory array through the second LIO 108. For example, when the first memory array is selected, the data may be transferred from the first memory array to the first sense amplifier 210, and then from the first sense amplifier 210 to the first local latch circuit 220. The GIO 106 can read and latch the data from the first local latch circuit 220.

In some embodiments, the GCTRL 116 may include a clock generation block 250 and an address latch 260. In some embodiments, the clock generation block 250 may receive a clock source signal (e.g., CLK), a self-time signal (e.g., RESET), an address decoder signal (e.g., A[0:n]), and a write enable signal (e.g., WEN, CS). The clock source signal may provide an internal clock (ICLK) signal to the LCTRL block (e.g., first LCTRL 114, second LCTRL 118) and the WL decoder block 112, 120. In some embodiments, the address latch 260 can receive different portions (e.g., different bits) of an address signal, e.g., A[ ]. The address latch 260 may identify a selected bank (e.g., the first memory bank or the second memory bank) based on the address signal (e.g., A[ ]). The address latch 260 may generate a BSB signal to activate/open one of the local latch circuits (e.g., first SLATCH, second SLATCH). For example, when BSLB1 signal is 1 and BSL1 signal is 0, the PMOS of the second local latch 108 can be high, and the NMOS of the second local latch 108 can be low, causing the second local latch 230 to be off. In some embodiments, the first local latch circuit 220 and the second local latch circuit 230 can be configured to be alternately activated, which can ensure no glitches occur on the signals.

In some embodiments, the first LCTRL 114 can include a local clock generation block 270. The local clock generation block 270 may include a sense amplifier enable/sense amplifier pre-charge bit line (SA/SAPRB) driver and a BL pre-charge driver. In some embodiments, the SA/SAPRB driver can provide different control signals (e.g., TCKSM, TCKSN, CKPWL) based on the GCKPB signal to control (e.g., activate or deactivate) respective circuits included in the first LIO 104. Similarly, the BL pr-charge driver can provide at least one control signal (e.g., TCKSM, TCKSN, CKPWL) based on the GCKPB signal to control (e.g., activate or deactivate) a circuit included in the first LIO block 104.

In some embodiments, the second LCTRL 118 can include a local clock generation block 280. The local clock generation block 280 may include a sense amplifier enable/sense amplifier pre-charge bit line (SA/SAPRB) driver and a BL pre-charge driver. In some embodiments, the SA/SAPRB driver can provide different control signals (e.g., TCKSM, TCKSN, CKPWL) based on the GCKPB signal to control (e.g., activate or deactivate) respective circuits included in the second LIO 108. Similarly, the BL pr-charge driver can provide at least one control signal (e.g., TCKSM, TCKSN, CKPWL) based on the GCKPB signal to control (e.g., activate or deactivate) a circuit included in the second LIO block 108.

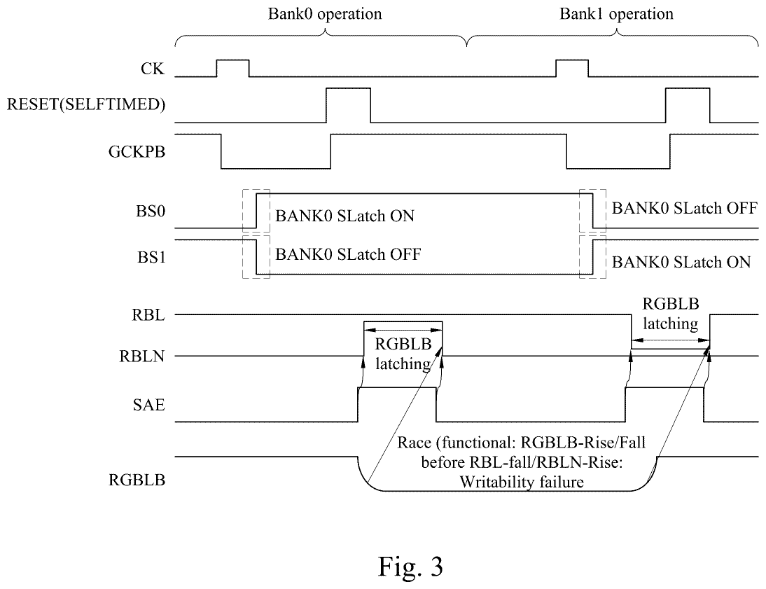

FIG. 3 illustrates example waveforms 300 of various signals while operating the memory circuit 100 of FIG. 2 and FIG. 1, in accordance with some embodiments. As shown in FIG. 3, at the beginning of an operation cycle, the CK signal goes high, causing the internal clock GCKPG signal to go low. The GCKPG signal will go high again when the RESET signal is activated. The BS0 and BS1 signals can be used to select the corresponding local latch circuit (e.g., BANK0 S-Latch, BANK1 S-Latch). The BS0 and BS1 signals are complementary, ensuring that only one bank's latch is active at any time. For instance, when the BS0 signal goes high, the BANK0 S-Latch turns ON (e.g., latching state/mode), and when the BS1 signal goes low, the BANK1 S-Latch turns OFF. This selection mechanism controls which bank is active during the read or write operations. Next, once the SAE signal goes high, the RBLN signal will also go high, initiating a latching operation, allowing data from the memory array to be written into the local latch circuit (e.g., BANKO S-Latch). As the SAE signal returns low, the RBLN signal also goes low, signaling the completion of the Bank 0 operation for the RGBLB signal (e.g., data).

In the next operation, if data is to be written into the Bank 1 latch circuit, the BS0 signal will go low, turning the BANK 0 S-Latch OFF, while the BS1 signal goes high, turning the BANK 1 S-Latch ON (e.g., latching state/mode). The BS0 and BS1 signals are complementary, ensuring that only one bank's latch is active at any time. As the SAE signal goes high again, the RBL signal will go low, triggering the latching operation for the RGBLB signal in Bank 1 (e.g., BANK1 S-Latch). As the SAE signal returns low, the RBL signal also goes high, signaling the completion of the Bank 1 operation for the RGBLB signal (e.g., data). In certain embodiments, only one race condition exists: the race between the rising and falling of the RGBLB signal and the falling of the RBL signal or the rising of the RBLN signal. This race needs to be carefully managed to avoid a writability failure.

In a read active cycle, the internal clock GCKPB sets the BSL0/BSLB1 signals in the selected local I/O (LIO) based on the address selection A[ ], as illustrated in FIG. 3. A high BSL0/BSL1 signal turns on BANK0 S-Latch/BANK1 S-Latch and turns off BANK1 S-Latch/BANK0 S-Latch, respectively. The RESET signal, generated by the self-timing circuit, sets the SAE0/SAE1 signals high when a sufficient differential voltage is developed on the bit-lines from the memory array block. Depending on whether the data on the bit-lines is 0 or 1, the SAE signal sets RBL-0 and RBLN-1 for data 0, or RBL-1 & RBLN-0 for data 1. The RBL and RBLN signals are then written into the appropriate local latch circuit (e.g., first SLATCH 220, second SLATCH 230). The write pulse width for the local latch circuit is determined by the SAE pulse width, and no additional tracking circuits are required for latching the readout data, simplifying the design.

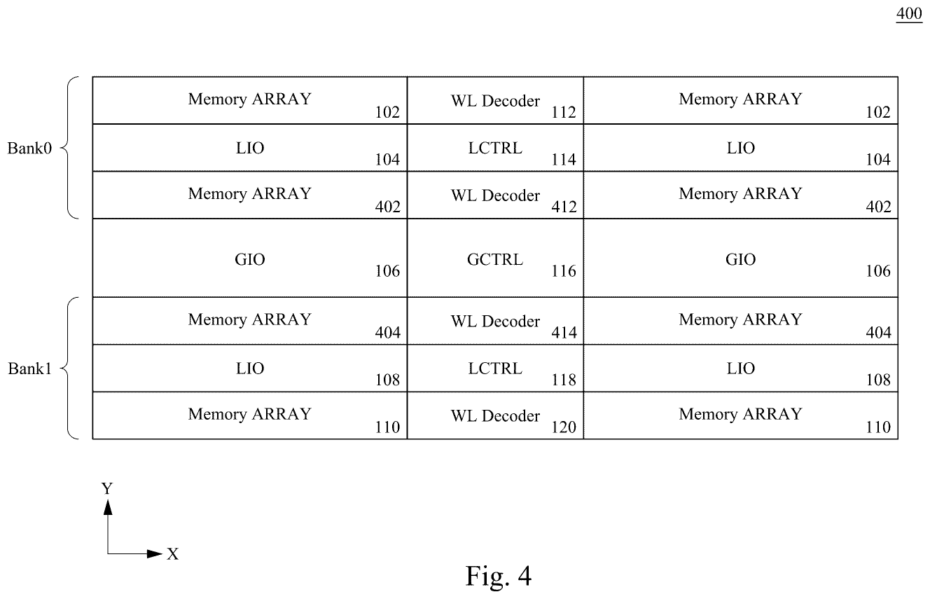

FIG. 4 illustrates another example block diagram of a memory circuit 400, in accordance with some embodiments. FIG. 4 illustrates an alternative example of FIG. 1 by introducing additional memory arrays 402, 404 between a local input/output (I/O) circuit (LIO) block (e.g., 104, 108) and a global I/O circuit (GIO) block 106. The memory circuit 400 may include a plurality of memory array blocks (e.g., 102, 110, 402, 404), a plurality of local input/output (I/O) circuit (LIO) blocks (e.g., 104, 108), and a global I/O circuit (GIO) block 106. In some embodiments, a plurality of local latch circuits can be physically disposed in the plurality of local I/O circuit blocks (e.g., 104, 108). In some embodiments, the plurality of local latch circuits can be configured to be alternately activated, which can ensure no glitches occur on the signals. The memory circuit 400 of FIG. 4 is substantially similar to the memory circuit 100 of FIG. 1, except for the additional memory arrays 402, 404. The proposed memory circuit eliminates all signal races involved in reading from multibank SRAM memory, thereby improving both the yield and performance of the memory.

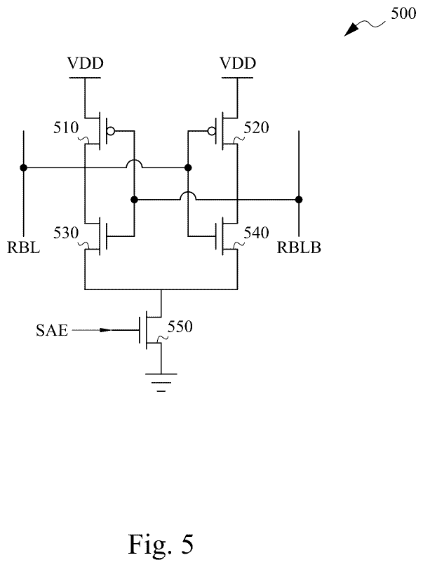

FIG. 5 illustrates an example circuit diagram of a sense amplifier 500, in accordance with various embodiments of the present disclosure. The sense amplifier 500 can be a non-limiting implementation of the sense amplifier 210, 240 described above. Accordingly, the sense amplifier 500 can be coupled to a pair of RBL and RBLB that can be pre-charged by an SAPCH circuit, and the RBL and RBLB can be coupled from a selected BL and a selected BLB prior to a sense operation through an activated read pass-gate circuit.

The sense amplifier 500 includes transistors 510, 520, 530, 540, and 550, where the transistors 510 and 520 are each implemented as a PMOS FET and the transistors 530 to 550 are each implemented as an NMOS FET. The transistors 510 and 530 can form a first inverter and the transistors 520 and 540 can form a second inverter, with the first inverter and the second inverter cross-coupled to each other to operatively serve as a latch. The transistor 550, gate by a sense enable signal (e.g., an SAE signal), can serve as a switch of the sense amplifier 500. For example, the sense amplifier 500 can be activated to sense and amplify an input value only when the transistor 550 is activated or turned on.

Prior to the sense operation, nodes DL_IN and DLB_IN are typically pre-charged by a corresponding SAPCH circuit to a voltage less than a supply voltage VDD, for example, VDD/2. After the two nodes DL_IN and DLB_IN are pre-charged, a small voltage sensed from a selected memory cell is coupled onto the sense node DL_IN or DLB_IN; the other node will remain at its pre-charged voltage. Next, the sense amplifier 500 can be enabled by the SAE signal, which causes the transistor 550 to couple the latch (formed by the cross-coupled first and second inverters) to a ground or other voltage supply (this could also be negative, for example) to allow current to flow through transistors 510 to 540. Since one of the inputs DL_IN or DLB_IN will be greater than or less than a threshold potential for one of the transistors, while the other input is at an intermediate value, the latch will latch that input value. The latch can amplify that input value due to the gain of the transistors in the latch, the small signal voltage sensed will be amplified to a full logic value for output to a corresponding output latch.

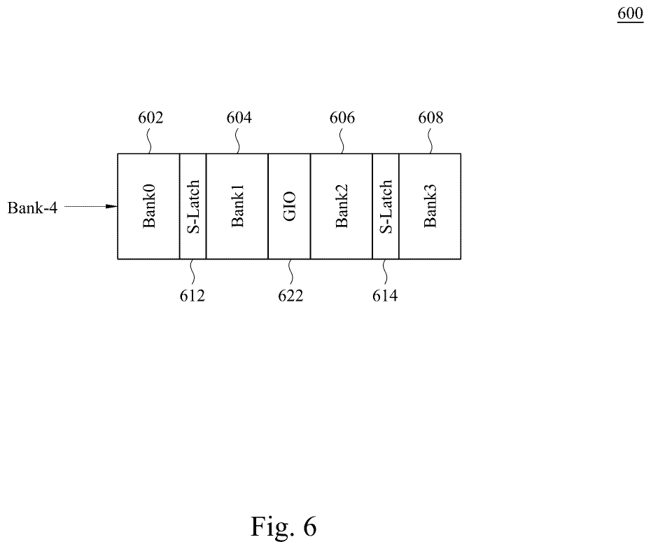

FIG. 6 illustrates another example block diagram of a memory circuit 600, in accordance with some embodiments. FIG. 6 illustrates an alternative example of FIG. 1 by introducing Bank-4 architecture. The memory circuit 600 may include a plurality of memory bank blocks (e.g., Bank0 602, Bank1 604, Bank2 606, Bank3 608), a plurality of local latch circuit blocks (e.g., S-Latch 612, 614), and a global I/O circuit (GIO) block 622. In some embodiments, the plurality of local latch circuits can be configured to be alternately activated, which can ensure no glitches occur on the signals. The memory circuit 600 of FIG. 6 is substantially similar to the memory circuit 100 of FIG. 1, except for the four-bank architecture. The implementation of Bank-4 architecture is versatile and can be implemented in external clock-phase-based SRAM memory, where the external clock phase can be used instead of self-timed logic to control read and write operations. By using external clock-phase timing, the design is adaptable to various architectures and can improve timing flexibility in multi-bank memory systems, offering benefits in scaling for larger memory configurations. The proposed method is demonstrated using a Bank-4 architecture, but it can be applied to memory architectures with more than four banks, such as Bank-4, Bank-8, and beyond.

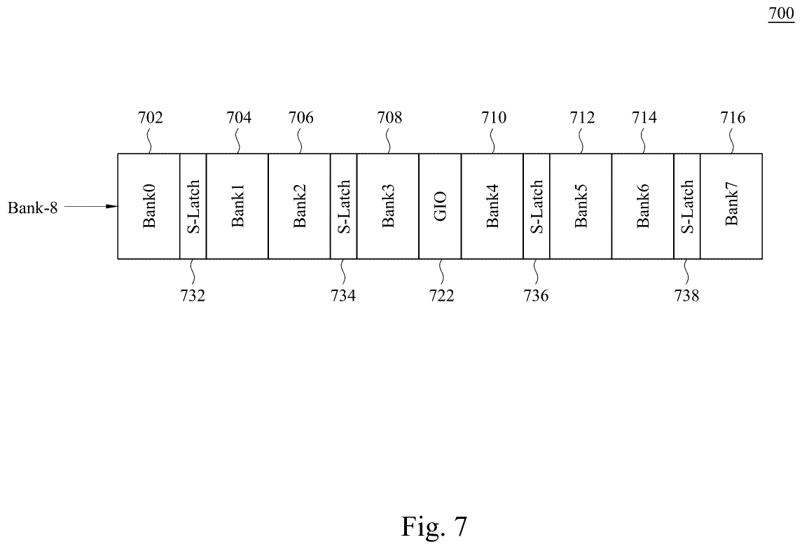

FIG. 7 illustrates another example block diagram of a memory circuit 700, in accordance with some embodiments. FIG. 7 illustrates an alternative example of FIG. 1 by introducing Bank-8 architecture. The memory circuit 700 may include a plurality of memory bank blocks (e.g., Bank0 702, Bank1 704, Bank2 706, Bank3 708, Bank4 710, Bank5 714, Bank6714, Bank7 716), a plurality of local latch circuit blocks (e.g., S-Latch 732, 734, 736, 738), and a global I/O circuit (GIO) block 722. In some embodiments, the plurality of local latch circuits can be configured to be alternately activated, which can ensure no glitches occur on the signals. The memory circuit 700 of FIG. 7 is substantially similar to the memory circuit 100 of FIG. 1, except for the eight-bank architecture. The implementation of Bank-8 architecture is versatile and can be implemented in external clock-phase-based SRAM memory, where the external clock phase can be used instead of self-timed logic to control read and write operations. By using external clock-phase timing, the design is adaptable to various architectures and can improve timing flexibility in multi-bank memory systems, offering benefits in scaling for larger memory configurations. The proposed method is demonstrated using a Bank-8 architecture, but it can be applied to memory architectures with more than eight banks, such as Bank-8, Bank-16, and beyond.

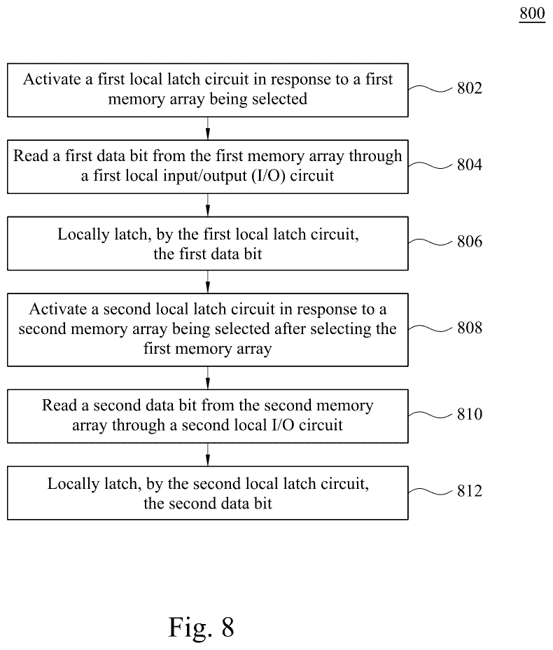

FIG. 8 illustrates an example flow chart for operating a memory circuit, in accordance with some embodiments. It is noted that the method 800 is merely an example, and is not intended to limit the present disclosure. Accordingly, it is understood that any additional operations may be provided during, before, and after the method 800 of FIG. 8, and that some other operations may only be briefly described herein. The method 800 may be utilized to operate the memory circuit 100, and thus, operations of the method 800 will be discussed in conjunction with the components discussed in FIGS. 1-7.

In brief overview, the method 800 starts with operation 802 of activating a first local latch circuit 220 in response to a first memory array 102 being selected. For instance, when a BS0 signal goes high, the first local latch circuit 220 (e.g., latching state/mode) turns ON, and when a BS1 signal goes low, a second local latch circuit 230 turns OFF. In some embodiments, the first local latch circuit 220 can be operatively coupled to a first local I/O circuit 104. In some embodiments, the first local latch circuit 220 can be physically disposed in the first local I/O circuit 104. In certain embodiments, the first local latch circuit 220 can be physically disposed next to the first local I/O circuit 104. In some embodiments, in response to the first local latch circuit 220 being activated, the memory circuit 100 may activate a first sense amplifier 210 of the first local I/O circuit 104.

Corresponding to operation 804 of FIG. 8, the memory circuit 100 may read a first data bit (e.g., SAE0 signal) from the first memory array 102 through a first local I/O circuit 104. In some embodiments, the first local I/O circuit 104 can be operatively coupled to the first memory array 102. The first local I/O circuit 104 can be operatively coupled to a GIO block 106. In some embodiments, the first local I/O circuit 104 can be physically disposed between the first memory array 102 and the global I/O circuit block 106 along a lateral direction (e.g., Y direction).

Corresponding to operation 806 of FIG. 8, the memory circuit 100 may locally latch, by the first local latch circuit 220, the first data bit (e.g., RGBLB signal). For example, once the SAE0 signal goes high, the RBLN0 signal will also go high, initiating a latching operation, allowing data from the memory array to be written into the first local latch circuit 220. As the SAE0 signal returns low, the RBLN0 signal also goes low, signaling the completion of first memory array operation for the RGBLB signal (e.g., data).

Corresponding to operation 808 of FIG. 8, the memory circuit 100 may activate a second local latch circuit 230 in response to a second memory array 110 being selected after selecting the first memory array 102. In some embodiments, the first local latch circuit 220 and the second local latch circuit 230 can be configured to be alternately activated. For example, the BS0 signal can go low, turning the first local latch circuit 220 OFF, while the BS1 signal goes high, turning the second local latch circuit 230 ON (e.g., latching state/mode). In some embodiments, the second local latch circuit 230 can be operatively coupled to the second local I/O circuit 108. In some embodiments, the second local latch circuit 230 can be physically disposed in the second local I/O circuit 108. In certain embodiments, the second local latch circuit 230 can be physically disposed next to the second local I/O circuit 108. In some embodiments, in response to the second local latch circuit 230 being activated, the memory circuit 100 may activate a second sense amplifier 240 of the second local I/O circuit 108.

Corresponding to operation 810 of FIG. 8, the memory circuit 100 may read a second data bit (e.g., SAE1 signal) from the second memory array 110 through a second local I/O circuit 108. The second local I/O circuit 108 can be operatively coupled to the second memory array 110. The second LIO 108 can be operatively coupled to the GIO 106. In some embodiments, the second local I/O circuit 108 can be physically disposed between the second memory bank 110 and the global I/O circuit 106 along a lateral direction (e.g., Y-direction) Corresponding to operation 812 of FIG. 8, the memory circuit 100 may locally latch, by the second local latch circuit 230, the second data bit (e.g., RGBLB signal). As the SAE1 signal goes high, the RBL1 signal can go low, triggering the latching operation for the RGBLB signal in second local latch circuit 230. As the SAE1 signal returns low, the RBL1 signal also goes high, signaling the completion of the second memory array operation for the RGBLB signal (e.g., data). In some embodiments, the first local latch circuit and the second local latch circuit can be configured to be alternately activated.

In one aspect of the present disclosure, a memory circuit is disclosed. The memory circuit may include a first memory bank including a first memory array; a first local input/output (I/O) circuit operatively coupled to the first memory bank; a second memory bank including a second memory array; a second local I/O circuit operatively coupled to the second memory bank; a global I/O circuit operatively coupled between the first local I/O circuit and the second local I/O circuit; a first local latch circuit operatively coupled to the first local I/O circuit; and a second local latch circuit operatively coupled to the second local I/O circuit. The global I/O circuit can be configured to latch a data bit read from the first memory array through the first local I/O circuit or read from the second memory array through the second local I/O circuit. The first local latch circuit can be configured to be activated to latch the data bit when read from the first memory array. The second local latch circuit can be configured to be activated to latch the data bit when read from the second memory array. The first local latch circuit and the second local latch circuit can be configured to be alternately activated.

In another aspect of the present disclosure, a memory circuit is disclosed. The memory circuit may include a global I/O circuit operatively coupled to a first memory array through a first local I/O circuit and operatively coupled to a second memory array through a second local I/O circuit; a first local latch circuit, upon being activated, configured to locally latch the data bit read from the first memory array; and a second local latch circuit, upon being activated, configured to locally latch the data bit read from the second memory array. The global I/O circuit can be configured to latch a data bit read from the first memory array through the first local I/O circuit or read from the second memory array through the second local I/O circuit. The first local latch circuit and the second local latch circuit can be configured to be alternately activated.

In yet another aspect of the present disclosure, a method for operating a memory circuit is disclosed. The method may include, in response to a first memory array being selected, activating a first local latch circuit. The method may include reading a first data bit from the first memory array through a first local input/output (I/O) circuit. The method may include locally latching, by the first local latch circuit, the first data bit. The method may include, in response to a second memory array being selected after selecting the first memory array, activating a second local latch circuit. The method may include reading a second data bit from the second memory array through a second local I/O circuit. The method may include locally latching, by the second local latch circuit, the second data bit.

As used herein, the terms “about” and “approximately” generally indicates the value of a given quantity that can vary based on a particular technology node associated with the subject semiconductor device. Based on the particular technology node, the term “about” can indicate a value of a given quantity that varies within, for example, 10-30% of the value (e.g., +10%, ±20%, or ±30% of the value).

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

1. A memory circuit, comprising:
a first memory bank including a first memory array;
a first local input/output (I/O) circuit operatively coupled to the first memory bank;
a second memory bank including a second memory array;
a second local I/O circuit operatively coupled to the second memory bank;
a global I/O circuit operatively coupled between the first local I/O circuit and the second local I/O circuit, wherein the global I/O circuit is configured to latch a data bit read from the first memory array through the first local I/O circuit or read from the second memory array through the second local I/O circuit;
a first local latch circuit operatively coupled to the first local I/O circuit, wherein the first local latch circuit is configured to be activated to latch the data bit when read from the first memory array;
a second local latch circuit operatively coupled to the second local I/O circuit, wherein the second local latch circuit is configured to be activated to latch the data bit when read from the second memory array;
wherein the first local latch circuit and the second local latch circuit are configured to be alternately activated.

2. The memory circuit of claim 1, wherein the first local I/O circuit is coupled to the first memory array through a pair of first bit lines, and the second local I/O circuit is coupled to the second memory array through a pair of second bit lines.

3. The memory circuit of claim 2, wherein the first local I/O circuit includes a first sense amplifier selectively activated by a first enable signal, and the second local I/O circuit includes a second sense amplifier selectively activated by a second enable signal.

4. The memory circuit of claim 3, wherein when the first sense amplifier is activated, one of the pair of first bit lines rises and the other of the pair of first bit lines falls, causing the data bit to be locally latched by the first local latch circuit.

5. The memory circuit of claim 4, wherein the first local latch circuit is activated prior to the first sense amplifier being activated.

6. The memory circuit of claim 5, wherein the first local latch circuit is activated in response to the first memory bank being selected.

7. The memory circuit of claim 3, wherein when the second sense amplifier is activated, one of the pair of second bit lines rises and the other of the pair of second bit lines falls, causing the data bit to be locally latched by the second local latch circuit.

8. The memory circuit of claim 7, wherein the second local latch circuit is activated prior to the second sense amplifier being activated.

9. The memory circuit of claim 8, wherein the second local latch circuit is activated in response to the second memory bank being selected.

10. The memory circuit of claim 1, wherein the first memory bank includes a plurality of the first memory arrays, and the second memory bank includes a plurality of the second memory arrays.

11. The memory circuit of claim 10, wherein the global I/O circuit is physically disposed between the first memory bank and the second memory bank along a lateral direction, with the first local I/O circuit interposed between adjacent ones of the first memory arrays along the lateral direction and with the second local I/O circuit interposed between adjacent ones of the second memory arrays along the lateral direction.

12. A memory circuit, comprising:
a global I/O circuit operatively coupled to a first memory array through a first local I/O circuit and operatively coupled to a second memory array through a second local I/O circuit, wherein the global I/O circuit is configured to latch a data bit read from the first memory array through the first local I/O circuit or read from the second memory array through the second local I/O circuit;
a first local latch circuit, upon being activated, configured to locally latch the data bit read from the first memory array;
a second local latch circuit, upon being activated, configured to locally latch the data bit read from the second memory array;
wherein the first local latch circuit and the second local latch circuit are configured to be alternately activated.

13. The memory circuit of claim 12, wherein the first local I/O circuit is coupled to the first memory array through a pair of first bit lines, and the second local I/O circuit is coupled to the second memory array through a pair of second bit lines.

14. The memory circuit of claim 13, wherein when a first sense amplifier is activated, one of the pair of first bit lines rises and the other of the pair of first bit lines falls, causing the data bit to be locally latched by the first local latch circuit.

15. The memory circuit of claim 14, wherein when the first sense amplifier is activated, one of the pair of first bit lines rises and the other of the pair of first bit lines falls, causing the data bit to be locally latched by the first local latch circuit.

16. The memory circuit of claim 15, wherein the first local latch circuit is activated prior to the first sense amplifier being activated.

17. The memory circuit of claim 14, wherein when a second sense amplifier is activated, one of the pair of second bit lines rises and the other of the pair of second bit lines falls, causing the data bit to be locally latched by the second local latch circuit.

18. The memory circuit of claim 17, wherein the second local latch circuit is activated prior to the second sense amplifier being activated.

19. A method for operating a memory circuit, comprising:
in response to a first memory array being selected, activating a first local latch circuit;
reading a first data bit from the first memory array through a first local input/output (I/O) circuit;
locally latching, by the first local latch circuit, the first data bit;
in response to a second memory array being selected after selecting the first memory array, activating a second local latch circuit;
reading a second data bit from the second memory array through a second local I/O circuit; and
locally latching, by the second local latch circuit, the second data bit.

20. The method of claim 19, comprising:
in response to the first local latch circuit being activated, activating a first sense amplifier of the first local I/O circuit; and
in response to the second local latch circuit being activated, activating a second sense amplifier of the second local I/O circuit.
